(19) United States
(12) Patent Application Publication
(10) Pub. No.: US 2025/0194276 A1
(43) Pub. Date: Jun. 12, 2025

(54) IMAGING SYSTEM HAVING MICROLENS AND PHOTO-ELECTRIC DEVICE AND MANUFACTURING METHOD

(71) Applicant: ChangXin Memory Technologies, Inc., Hefei City (CN)

(72) Inventor: Kanyu Cao, Hefei City (CN)

(21) Appl. No.: 17/790,457

(22) PCT Filed: Apr. 26, 2022
(86) PCT No.: PCT/CN2022/089376

§ 371 Date: Jun. 30, 2024

(30) Foreign Application Priority Data
Dec. 24, 2021 (CN) 202111603725.6

(51) Int. Cl. H10F 39/00; H10F 39/12

(52) U.S. Cl. CPC H10F 39/8063; H10F 39/024; H10F 39/12; H10F 39/8053; H10F 39/8057

(57) ABSTRACT

The present disclosure provides an imaging system having a microlens array, a photoelectric conversion device, and a manufacturing method. The microlens array includes a first microlens array and a first light-transmitting part, and the first light-transmitting part is disposed on the first microlens array, the refractive index of the first light-transmitting part is greater than the refractive index of the ambient medium. A first light-transmitting part with a high refractive index is arranged on the first microlens array to change the wavelength of the incident light, so that the light with a shorter wavelength is imaged by the first microlens array to form an object image with a smaller diameter in its image size, thereby increasing the resolution of the imaging system.

### CROSS REFERENCE

This application claims the priority of the Chinese patent application with the application number CN202111603725.6 and the application title “IMAGING SYSTEM HAVING MICROLENS AND PHOTOELECTRIC DEVICE AND MANUFACTURING METHOD”, filed with the China National Intellectual Property Administration on Dec. 24, 2021, the content of which is incorporated in its entirety herein.

### TECHNICAL FIELD

The application relates to the technical field of semiconductors, in particular to an imaging system including a microlens array, a photoelectric conversion device, and a manufacturing method making the same.

### BACKGROUND

Image sensors are a photoelectric conversion devices that convert light images on the photosensitive surfaces into electrical signals related to the light images. They are widely used in electronic products. Among them, the more common image sensors are CMOS image sensors (referred to as CIS), and charge-coupled image sensors (referred to as CCD).

A CIS image sensor usually includes a photosensitive element, a microlens array and a peripheral circuit. The microlens array is arranged on the photosensitive element, and the peripheral circuit is connected to the photosensitive element. When external light is collected by the microlens array, it enters the photosensitive element. The photosensitive element can convert the optical signal into an electrical signal, and the electrical signal is output through the peripheral circuit for imaging.

### SUMMARY

A first embodiment of the present disclosure provides a microlens array, including:
a first microlens array;

a first light-transmitting part, the first light-transmitting part is arranged on the first microlens array, and the first light-transmitting part transmits the light propagating in the ambient medium to the first microlens array wherein, the refractive index of the first light-transmitting part is greater than the refractive index of the ambient medium.

In some embodiments, the refractive index of the first light-transmitting part is greater than the refractive index of the first microlens array.

In some embodiments, a second light-transmitting part is further included, the second light-transmitting part is disposed between the first light-transmitting part and the first microlens array, and the refractive index of the second light-transmitting part is smaller than the refractive index of the first light-transmitting part and the refractive index of the first microlens array.

In some embodiments, the first microlens array includes a microconvex lens array or a microconcave lens array.

In some embodiments, the first microlens array includes a plurality of first microlenses, the first light-transmitting part includes a plurality of first light-transmitting elements, and the first light-transmitting elements each corresponds to one or more of the first microlenses; wherein, the first microlenses each comprises a convex lens or a concave lens.

In some embodiments, each of the first light-transmitting elements includes a second microlens, a second microlens array composed of a plurality of the second microlenses, and one of the second microlenses corresponds to one or more of the first microlenses.

In some embodiments, the second microlenses each has a second focal point formed in the second light-transmitting part.

In some embodiments, the second light-transmitting part has a first thickness, and the maximum distance from the second focal point to the top surface of the second light-transmitting part is no greater than half of the first thickness.

In some embodiments, the first microlenses each has a first curvature and the second microlenses each has a second curvature, the second curvature being different from the first curvature.

A second embodiment of the present disclosure provides a photoelectric conversion device, including: a light-sensing element layer and the microlens array described in the above embodiment.

The microlens array is disposed on the light-sensing element layer.

In some embodiments, the light-sensing element layer includes a filter layer, the filter layer includes a plurality of filter regions, and one of the filter regions corresponds to one or more of the first microlenses.

In some embodiments, the photosensitive layer further includes a light-sensing element layer, the light-sensing element layer includes a plurality of photosensitive elements, and one of the photosensitive elements corresponds to one or more of the first microlenses.

In some embodiments, the first microlens has a first focal point, the first focal point is formed in the photosensitive element layer, the photosensitive element layer has a second thickness, the maximum distance from the first focal point to the bottom surface of the first microlens is not less than half of the second thickness.

In some embodiments, an anti-reflection layer is further included, and the anti-reflection layer is disposed between the microlens array and the photosensitive layer.

A third embodiment of the present disclosure provides an imaging system, including the photoelectric conversion device described in the above embodiments.

The system also includes a signal processing unit that processes the signal output from the photoelectric conversion device.

A fourth embodiment of the present disclosure provides a method of manufacturing a photoelectric conversion device, the method includes:
providing a substrate, and forming a photosensitive element layer in the substrate.
forming a first microlens array on the photosensitive element layer, the first microlens array forming a first light receiving surface;
forming a first light-transmitting part covering the first light-receiving surface on the first microlens array, the top surface of the first light-transmitting part constitutes a second light-receiving surface, and the light propagating in the ambient medium passing through the second light-receiving surface is transmitted to the first light-receiving surface, wherein the refractive index of the first light-transmitting part is greater than the refractive index of the ambient medium.

In some embodiments, the step of forming a first microlens array on the photosensitive element layer includes:
depositing a first lens material layer on the substrate formed with the photosensitive element layer; and
patterning the first lens material layer according to the optical design to form a plurality of first microlenses connected to each other or arranged at intervals.

In some embodiments, after the step of forming a first microlens array on the photosensitive element layer, and before the step of forming a first light-transmitting part covering the first light receiving surface on the first microlens array, the method also includes:
forming a light-transmitting material layer on the first microlens array, and the refractive index of the light-transmitting material layer is smaller than that of the first microlens array;
removing part of the thickness of the light-transmitting material layer to form a second light-transmitting part, the second light-transmitting part at least fills the area between the adjacent first microlenses, and the second light-transmitting part has a flat top surface, wherein the refractive index of the second light-transmitting part is smaller than the refractive indices of the first light-transmitting part and the refractive indices of the first microlens array.

In some embodiments, the step of forming a first light-transmitting part covering the first light-receiving surface on the first microlens array includes:
forming a second lens material layer covering the second light-transmitting part, wherein the refractive index of the second lens material layer is greater than the refractive index of the first microlens array and the refractive index of the first light-transmitting part; and
patterning the second lens material layer according to the optical design to form a first light-transmitting part.

In some embodiments, the step of patterning the second lens material layer according to the optical design to form the first light-transmitting part includes:
patterning the second lens material layer to form a plurality of second light-transmitting parts connected to each other or arranged at intervals, each of the second light-transmitting parts includes a plurality of the second microlenses, which forms the second microlens array, one of the second microlenses corresponds to one or more of the first microlenses.

In the imaging system having the microlens arrays, the photoelectric conversion devices, and the manufacturing method provided by the embodiments of the present disclosure, a first light-transmitting part is provided on the first microlens array, and the refractive index of the first light-transmitting part is greater than that of the ambient medium. System set in this way can shorten the wavelength of the light transmitted to the first light-transmitting part than that the light propagating in the ambient medium, so that the light with a shorter wavelength is imaged by the first microlens array to form an object with a smaller image diameter, thereby increasing the resolution of the imaging system.

In addition to the technical problems solved by the above-described embodiments of the present disclosure the technical elements and the benefit of the imaging system, including the microlens assemblies, photoelectric conversion devices, and the manufacturing method will be described in further detail in the specific embodiments.

### BRIEF DESCRIPTION OF THE DRAWINGS

To illustrate the embodiments of the present disclosure more clearly, the accompanying drawings are included in the description of the embodiments. For those of ordinary skill in the art, other drawings can also be obtained from these drawings without creative effort.

FIG. 1 is a schematic structural diagram of a microlens array provided in the related art;

FIGS. 2 to 13 are schematic structural diagrams of the microlens arrays according to an embodiment of the present disclosure;

FIGS. 14 to 22 are schematic structural diagrams of the photoelectric conversion devices according to an embodiment of the present disclosure;

FIG. 23 is a schematic structural diagram of the photosensitive element layer provided by an embodiment of the present disclosure;

FIG. 24 is a schematic structural diagram of the imaging system provided by an embodiment of the present disclosure;

FIG. 25 is a process flow diagram of the method for manufacturing the photoelectric conversion device provided by an embodiment of the present disclosure;

FIG. 26 is a schematic structural diagram of a photosensitive element layer formed with a method for manufacturing the photoelectric conversion device provided by an embodiment of the present disclosure;

FIG. 27 is a schematic structural diagram of forming a first lens material layer in a method for manufacturing a photoelectric conversion device provided by an embodiment of the present disclosure;

FIG. 28 is a schematic structural diagram of a photoresist layer formed by the method for manufacturing the photoelectric conversion device provided by an embodiment of the present disclosure;

FIG. 29 is a schematic structural diagram of forming the first microlens array with the method of manufacturing the photoelectric conversion device provided by an embodiment of the present disclosure;

FIG. 30 is a schematic structural diagram of the light-transmitting material layer formed with the method for manufacturing the photoelectric conversion device provided by an embodiment of the present disclosure;

FIG. 31 is a first structural schematic diagram of the second light-transmitting part formed with the method for manufacturing the photoelectric conversion device provided by an embodiment of the present disclosure;

FIG. 32 is a second structural schematic diagram of the second light-transmitting part formed with the method for manufacturing the photoelectric conversion device provided by an embodiment of the present disclosure;

FIG. 33 is a first structural schematic diagram of the second lens material formed with the method for manufacturing the photoelectric conversion device provided by an embodiment of the present disclosure;

FIG. 34 is a second structural schematic diagram of forming a second lens material with the method for manufacturing the photoelectric conversion device provided by an embodiment of the present disclosure.

### DETAILED DESCRIPTION OF THE PREFERRED EMBODIMENTS

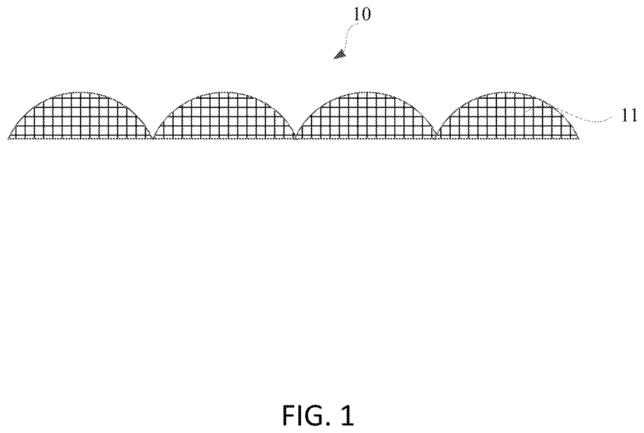

As shown in FIG. 1, in the related art, the microlens array 10 generally includes a plurality of microlenses 11, and each microlens 11 collects the light entering the microlens 11 to enhance the photosensitive element part corresponding to the microlens. The amount of light that can be received, but as the imaging systems develop toward more integrated and smaller size versions, the size of the microlenses 11 also get smaller. According to the imaging principle of light, the smaller the size of the microlens 11 is, the larger the diameter of the formed object image will be, as well as the lower the resolution of the imaging system will be.

According to the embodiment of the present disclosure, by disposing a first light-transmitting part on the first microlens array, wherein the refractive index of the first light-transmitting part is greater than the refractive index of the ambient medium, the wavelength of the light transmitted from the ambient medium into the first light-transmitting part reduces to a shorter wavelength so the object image formed will have a smaller diameter after being imaged by the first microlens array, thereby improving the resolution of the imaging system.

In order to make the above objects, features and advantages of the embodiments of the present disclosure more obvious and easy to understand, the technical solutions in the embodiments of the present disclosure will be clearly and completely described below with reference to the accompanying drawings in the embodiments of the present disclosure. Obviously, the described embodiments are only some, but not all, embodiments of the present disclosure. Based on the embodiments in the present disclosure, all other embodiments obtained by those of ordinary skill in the art without creative efforts shall fall within the protected scope of the present disclosure.

### Example 1

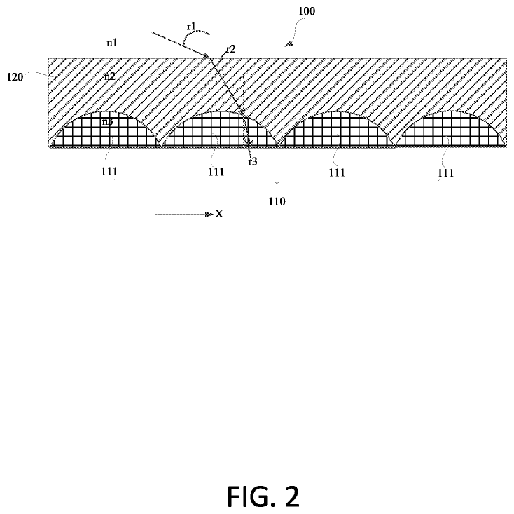

As shown in FIGS. 2 to 13, the microlens array 100 provided by the embodiments of the present disclosure can be applied to a photoelectric conversion device, for example, an image sensor.

The microlens array 100 includes a first microlens array 110 for being disposed on the light-sensing element layer in the photoelectric conversion device to guide incident light into the photosensitive element layer.

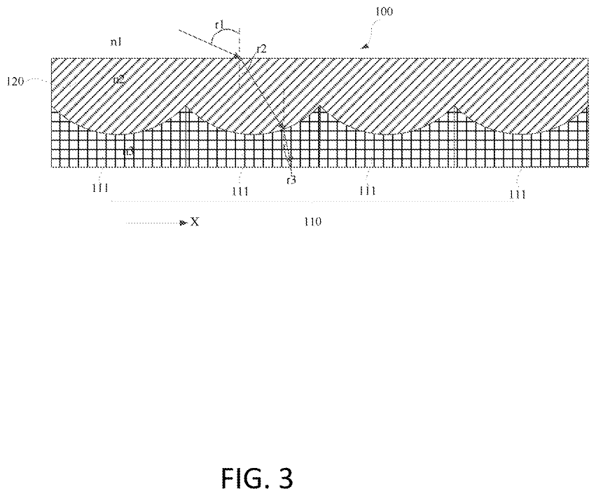

In this embodiment, the first .microlens array 110 includes a micro-convex lens array or a micro-concave lens array, the structures of which may be shown in FIG. 2 and FIG. 3.

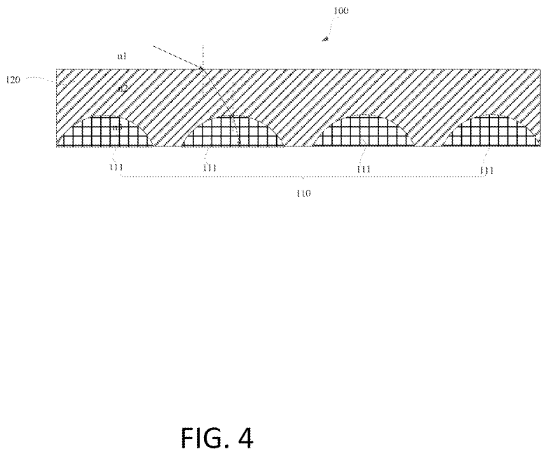

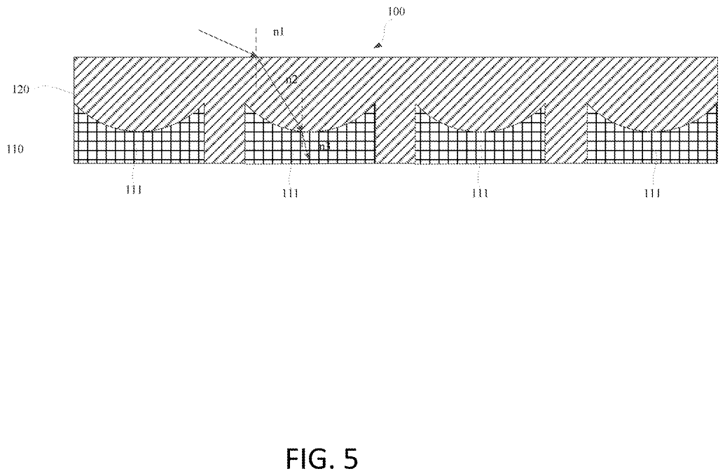

The first microlens array 110 includes a plurality of first microlenses 111, the first microlenses 111 are located in the same layer, and the first microlenses 111 can be closely arranged along the first direction, the structures of which are shown in FIG. 2 and FIG. 3 respectively. As shown, the first microlenses 111 may be arranged at intervals along the first direction, and their structures are shown in FIG. 4 and FIG. 5 respectively, wherein the distances between the adjacent first microlenses 111 may be equal or unequal. Specifically, it can be set according to the situation. In addition, the first direction can be understood as the X direction in FIG. 2.

The first light-transmitting part 120 is disposed on the first microlens array 110, and is used to transmit the light propagating in the ambient medium into the first microlens array 110, wherein the refractive index of the first light-transmitting part 120 is greater than that of the refractive index of the ambient medium.

In this embodiment, if the incident light directly propagates from the air to the first light-transmitting part 120, the propagation medium is air, and accordingly, the refractive index of the first light-transmitting part 120 is greater than that of the air; for another example, if the incident light from the air to another propagation media, and then from the other propagation media to the first light-transmitting part 120, the refractive index of the first light-transmitting part 120 is greater than the refractive index of the other propagation media.

The calculation formula of the diameter of the object image formed by the incident light after passing through the first microlens array 110: χ=1.22λf/d, where λ is the wavelength of the incident light of the medium, f is the focal length of the first microlens, and d is the diameter of the first microlens.

From the above formula it can be calculated that if the wavelength of the incident light is smaller, the diameter of the object image after imaging by the first microlens array 110 is correspondingly smaller, so that the resolution of the imaging system can be improved.

Based on the above theory, in this embodiment, a first light-transmitting part 120 is arranged on the first microlens array 110. The refractive index of the first light-transmitting part 120 is greater than the refractive index of the ambient medium. According to the relationship between the refractive index and the wavelength, the refractive index is greater, then the wavelength is smaller. Therefore, the light transmitted from the ambient medium to the first light-transmitting part 120 will be converted into light with a shorter wavelength when passing through the first light-transmitting part 120. In this way, the shorter wavelength when being imaged by the first microlens array 110, the object image will have a smaller image spot diameter, thereby improving the resolution of the imaging system.

In addition, it should be noted that when the incident light enters the first microlens array 110 through the first light-transmitting part 120, not only the wavelength of the incident light can be shortened, but also the refraction angle of the incident light can be reduced, so as to reduce the incidence of the stray incident light into adjacent interference occurring between the two adjacent first microlenses 111.

Exemplarily, continuing to refer to FIG. 2 and FIG. 3, it is assumed that the light is transmitted from the air to the first light-transmitting part 120, and the light entering the first light-transmitting part 120 from the air is called an incident light, which has a first incident angle r1, and the incident light has a large angle, for example, like the light propagating along the tangential direction of the right side of the number 2 from the left among the first microlens 111; the light refracted by the first light-transmitting part 120 is referenced as the first refracted light, which has a first refraction angle r2; the light refracted by the first microlens 111 is referenced as the second refracted light, which referenced as the second refracted angle r3.

The refractive index of air is denoted as n1, the refractive index of the first light-transmitting part 120 is denoted as n2, and the refractive index of the first microlens is denoted as n3.

According to the Snell's law calculating the refracted angles during the propagation of light in different medium layers: sin(r1)×(n1)=sin(r2)×(n2), since n2 is greater than n1, the first refracted angle r2 is smaller than the first incident angle r1, so that after the incident light with the first incident angle r1 is refracted by the first light-transmitting part 120, the first refracted light is deflected toward the second first microlens 111, preventing the first refracted light from being directed toward the first microlens 111. The third first microlens 111 is deflected, so that the incident light enters the first microlens array 110 with a smaller incident angle, so as to avoid interference of the incident light between two adjacent first microlenses 111.

In this way, the second refracted light formed by the incident light with a large angle is transmitted to one of the first microlenses 111 as much as possible, thereby reducing the interference of the incident light between the adjacent first microlenses 111. The amount of light received by the first microlens 111 can be increased, thereby improving the performance of a photoelectric conversion device using the microlens array.

It should be understood that the relationship between the refractive indices of the first light-transmitting part 120 and the first microlens array 110 may have different options. For example, the refractive index of the first light-transmitting part 120 may be smaller than that of the first microlens array 110. In this way, the wavelength of the incident light will be reduced again in the microlenses, so that the incident light has an even smaller wavelength, and an object image with a smaller diameter can be obtained, thereby improving the resolution of the imaging system; at the same time, the first light transmittance The refractive index of the element 120 may be smaller than the refractive index of the first microlens array 110, so that the incident light rays enter from low density medium to high density medium again, preventing interference of the incident light between two adjacent first microlenses 111.

For another example, the refractive index of the first light-transmitting part 120 may be greater than the refractive index of the first microlens array 110. In this embodiment, through the arrangement of the first light-transmitting part 120, the entering into the first light-transmitting part 120 has been shortened the light wavelength, and the refraction angle of the light entering the first light-transmitting part 120 is reduced, even if the first microlens array 110 micro-diffuses the incident light once, it will not affect the above mentioned beneficial effects, and also the effects of improving the resolution of the optical system and preventing the incident light from interfering between the two adjacent first microlenses 111 can still be achieved.

In this embodiment, whether the top surface of the first light-transmitting part 120 being flat or uneven will not limited in this embodiment.

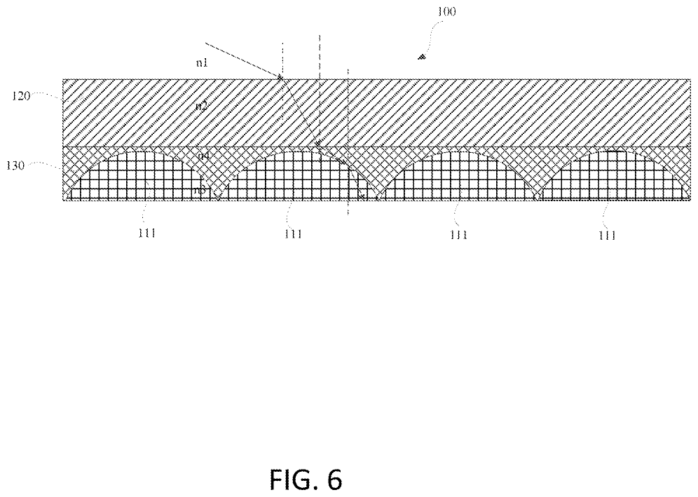

In some embodiments, as shown in FIGS. 6 to 10, the microlens array 100 further includes a second light-transmitting part 130, and the second light-transmitting part 130 is disposed between the first light-transmitting part 120 and the first microlens array 110. and the refractive index of the second light-transmitting part 130 is smaller than the refractive index of the first light-transmitting part 120 and the refractive index of the first microlens array 110.

The second light-transmitting parts 130 are at least partially filled between two adjacent first microlenses 111, wherein the top surface of the second light-transmitting part 130 may be flush with the top surfaces of the first microlenses 111, or lower than the first microlenses 111. The top surface of the microlenses 111, or the top surface of the second light-transmitting part 130 is higher than the top surface of the first microlenses 111. This arrangement can facilitate the setting of the first light-transmitting part 120 and improve the first light-transmitting part 120 for ease of preparation of the piece 120.

If the top surface of the second light-transmitting part 130 is flush with the top surface of the first microlenses 111 or higher than the top surface of the first microlenses 111, the edge of each of the first microlenses 111 is covered and wrapped with the second light-transmitting part 130, so that no matter how the large-angle light is incident from the edge of the first microlenses 111, it can be refracted by the first light-transmitting part 120 and the second light-transmitting part 130 to form a refracted light with a small angle, so that The light is deflected toward the corresponding first microlenses 111, thereby reducing the interference of incident light between the adjacent first microlenses 111.

In addition, the refracted light with the small angle can be used as the small-angle incident light entering the first microlens 111, which increases the amount of light received by the first microlens 111, thereby improving the performance of the photoelectric conversion device using the microlens array.

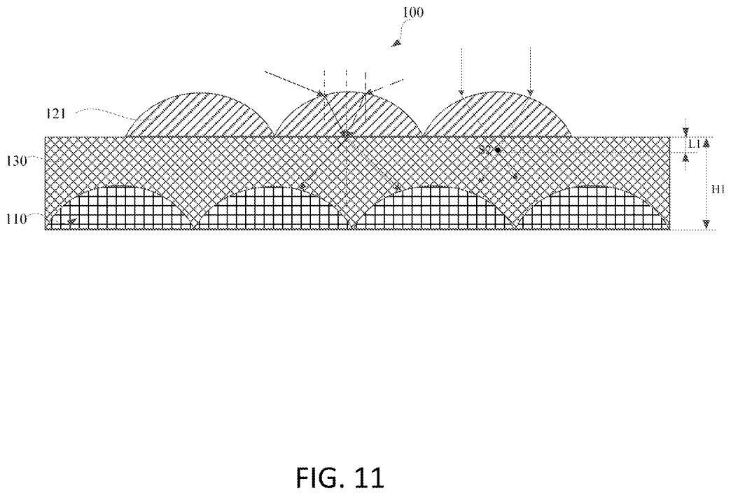

In this embodiment, as shown in FIG. 11, the second light-transmitting part 130 may have a first height H1, that is, the vertical distance between the top surface of the second light-transmitting part 130 and the bottom surface of the first microlens array 110.

In this embodiment, by increasing the height of the second light-transmitting part 130 along the direction perpendicular to the bottom surface of the first microlens array 110, the focal length of the imaging system can be reduced, and the object image formed after passing through the first microlens array 110 can be reduced. Also, the second refracted light formed by the incident light with a large incident angle is transmitted to one of the first microlenses 111, thereby decreasing the incident light into adjacent lenses. In addition, the amount of light received by the first microlenses 111 can be increased, thereby improving the performance of the photoelectric conversion device using the microlens array.

In some embodiments, the structure of the first light-transmitting part 120 can be selected to be in various shapes. In an example, for example, as shown in FIG. 6, the longitudinal cross-sectional shape of the first light-transmitting part 120 is a rectangle.

In this way, it can be ensured that the incident light with a large incident angle enters into the first light-transmitting part 120 from various locations on the top surface of the first light-transmitting part 120, the refraction angles of the light entering the first light-transmitting part 120 can be reduced. Further, the light emitted from the first microlens array 110 becomes an incident light within the incident angle, which then reduces the crosstalk of the incident light between adjacent photosensitive elements and improves the performance of the photoelectric conversion device.

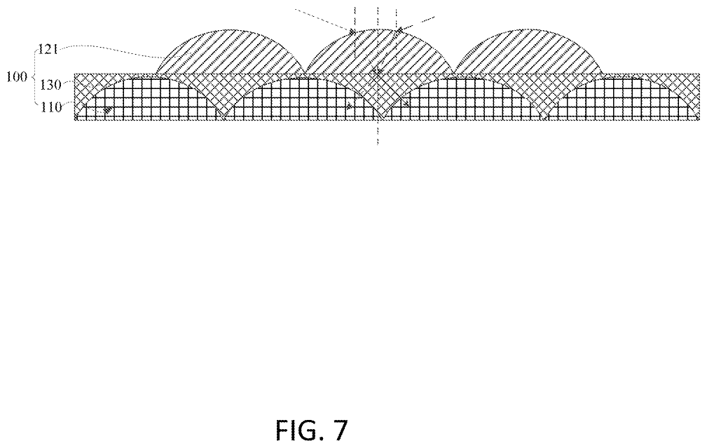

In another example, as shown in FIG. 7 to FIG. 11, the first light-transmitting part 120 includes a plurality of first light-transmitting elements 121, one first light-transmitting element 121 corresponds to one or more first microlenses 111, and also the projection of the first light-transmitting element 121 on the first microlens array 110 has an overlapping area with at least one first microlens 111.

For example, taking the orientation shown in FIG. 7 as an example, a portion of the projection of the first light-transmitting element 121 falls on the number one, from left to right, of the first microlens array 110 and the other portion falls on the number two of the first microlens 111.

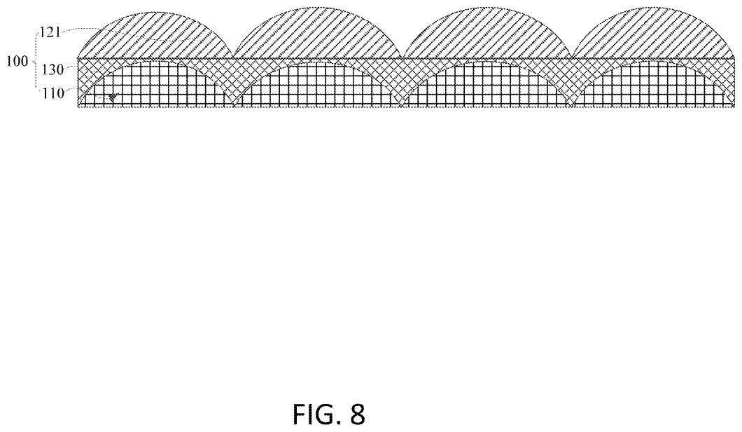

For another example, as shown in FIG. 8, the number of the first light-transmitting elements 121 is equal to the number of the first microlenses 111, and the projection of a first light-transmitting element 121 on the first microlens array 110 and the projection of a first microlenses 111 are coincident.

In this embodiment, by arranging the first light-transmitting elements 121 with a larger refractive index fall on the first microlens array 110, the loss of incident light at a large angle can be prevented, and at the same time, the light from both sides of the first light-transmitting elements 121 can be prevented from being lost. After the incident light is refracted by the first light-transmitting elements 121, it enters into different first microlenses 111, thereby reducing light interference between adjacent first microlenses 111. At the same time, the light propagating from the ambient medium into the first light-transmitting elements 121 can be converted into light with a shorter wavelength. In this way, the light with a shorter wavelength is imaged by the first microlens array 110 to form a light spot with an object image of a smaller diameter, thereby improving the resolution of the imaging system.

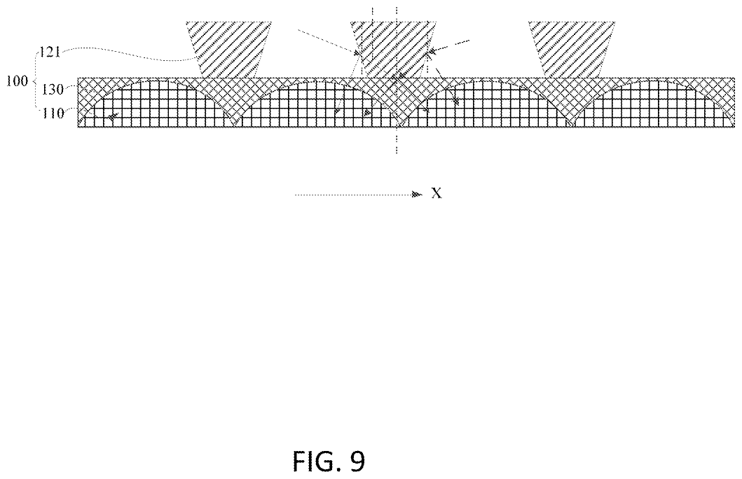

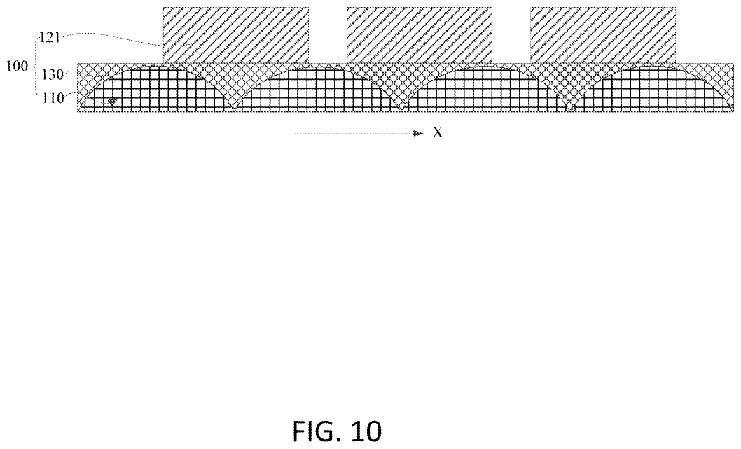

In some embodiments, the plurality of the first light-transmitting elements 121 may be arranged on the second light-transmitting part 130 at the intervals, that is, as shown in FIG. 9 and FIG. 10, the plurality of first light-transmitting elements 121 may also be connected and arranged in sequence on the second light-transmitting part 130, that is, as shown in FIG. 7 and FIG. 8, the opposite bottom edges of the adjacent two of the first light-transmitting elements 121 are connected together.

When there is an interval between the adjacent first light-transmitting elements 121, the first light-transmitting elements 121 can also reflect the incident light, so as to reflect part of the incident light into different first microlenses 111, reducing the phase difference of the light. Interference occurs between lights from adjacent first microlenses 111.

In an example, taking a cross section perpendicular to the plane where the first microlens array 110 is located as a longitudinal section, the longitudinal section shape of the first light-transmitting elements 121 may have a semi-elliptical shape, the structure of which is shown in FIGS. 7 and 8, the longitudinal cross-sectional shape of the first light-transmitting elements 121 can also be a trapezoid with a large top and a small bottom, and its structure is shown in FIG. 10.

When the longitudinal cross-sectional shape of the first light-transmitting elements 121 is a trapezoid and a rectangle, the first light-transmitting elements 121 each has a first side surface and a second side surface disposed opposite to each other along the first direction X. When light incidents on the first side and on the second side, the first side and the second side both play a blocking role, so that part of the light incident on the first side and part of the light on the second side are reflected, which are reflected into different first microlenses, to reduce light interference between adjacent first microlenses 111.

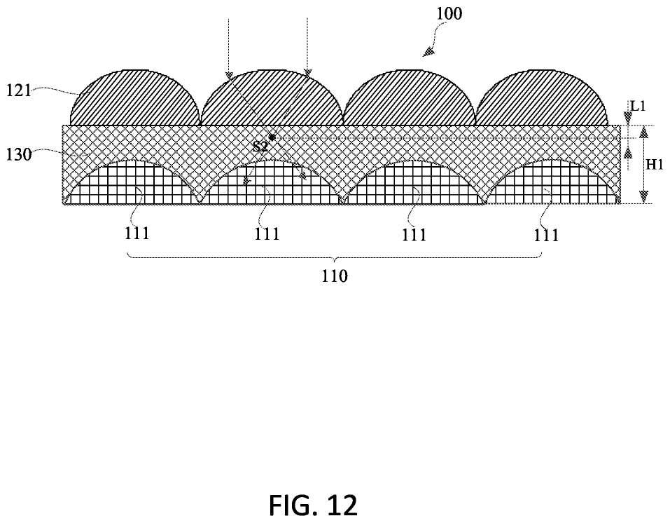

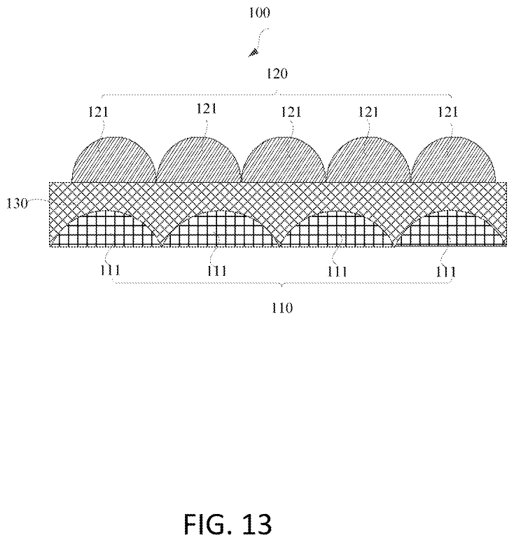

In some embodiments, as shown in FIG. 12 and FIG. 13, each of the first light-transmitting elements 121 includes a second microlens, the second microlenses form a second microlens array, and one second microlens corresponds to one of the plurality of first microlenses 111, wherein the second microlenses are convex lenses.

It should be noted that, in this embodiment, the plurality of second microlenses and the plurality of first microlenses 111 may be provided in a one-to-one correspondence. For example, as shown in FIG. 12, the number of the first microlenses 111 is four, the number of the second microlenses is also four, and each second microlens is disposed on one first microlens 111.

The plurality of second microlenses and the plurality of first microlenses 111 may not be in one-to-one correspondence. For example, as shown in FIG. 13, the number of the first microlenses 111 is four, and the number of the second microlenses is five.

Wherein, as shown in FIG. 12, the second microlens has a second focal point S2, and the second focal point S2 is formed in the second light-transmitting part 130, so that the light outputted by one of the second microlenses has a relatively dispersed state when entering one of the first microlenses 111 to increase the amount of light received by the first microlens, thereby ensuring that the light on the light-sensing element layer is also relatively uniform, so that the light received by each photosensitive element located in the light-sensing element layer is relatively uniform, The performance of the photoelectric conversion device is improved.

In some embodiments, the second light-transmitting part 130 has a first thickness H1, and the maximum distance L1 from the second focal point S2 to the top surface of the second light-transmitting part 130 is not greater than half of the first thickness H1.

It should be noted that the first thickness of the second light-transmitting part 130 is H1 shown in FIG. 12, which can also be understood as the thickness between the top surface of the second light-transmitting part 130 and the bottom surface of the first microlens array 110. The vertical distance, the distance from the second focus S2 to the top surface of the second light-transmitting part 130 is L1 shown in FIG. 11. In this embodiment, by adjusting the position of the second focus S2 in the second light-transmitting part 130, the portion of the incident light entering from the second lens is guided to different sides of the first microlens 111, and then crosstalk effect of light between adjacent photosensitive elements is prevented by the light condensing effect of the first microlens 111.

In addition, the focal length of the imaging system can also be reduced, and the diameter of the object image spot formed after passing through the first microlens array 110 can be reduced, thereby improving the resolution of the imaging system.

It should be noted that, in this embodiment, the curvature of each second microlens may be the same or different, which is not limited by this embodiment.

In some embodiments, each of the first microlenses 111 has a first curvature, the second microlenses each has a second curvature, and the second curvature is different from the first curvature.

On the premise that the second focus is on the second light-transmitting part 130, the curvatures of the first microlens 111 and the second microlens can be the same or different, so that there is more flexibility of the microlens array 100.

### Embodiment 2

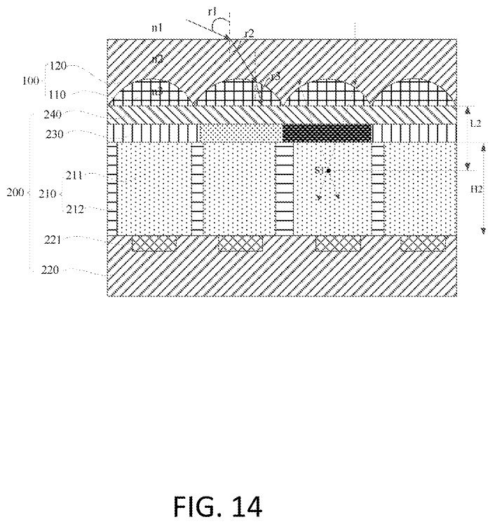

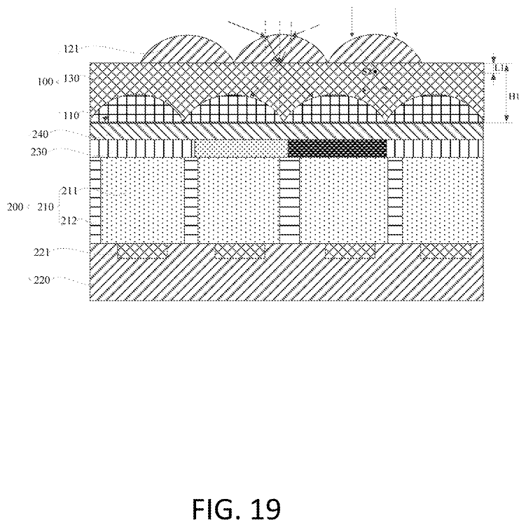

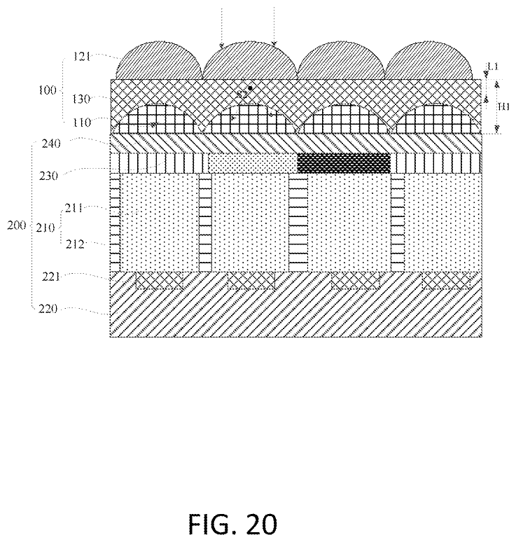

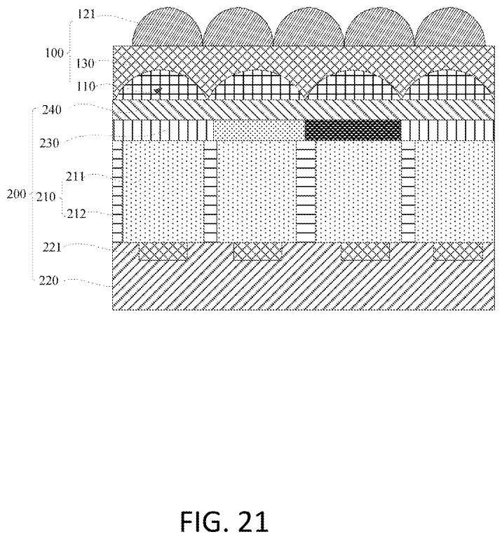

As shown in FIGS. 14 to 23, the embodiment of the present disclosure further provides a photoelectric conversion device, and the photoelectric conversion device can be applied to an imaging system, such as an image sensor.

The photoelectric conversion device includes the light-sensing element layer 200 and the microlens array 100 in the above embodiments.

The light-sensing element layer 200 includes a photosensitive element layer 210. The photosensitive element layer 210 includes a plurality of photosensitive elements 211 and an isolation structure 212 for separating each of the photosensitive elements 211. One photosensitive element 211 corresponds to one or more first microlenses 111. The photosensitive element The light 211 is used to receive the light transmitted through the one or more first microlenses 111 and convert the light signal of the light into an electrical signal, wherein the photosensitive element 211 includes a photodiode, but is not limited thereto.

In this embodiment, the first light-transmitting part 120 and the second light-transmitting part 130 are arranged on the first microlens array 110, wherein the refractive index of the first light-transmitting part 120 is greater than the refractive index of the ambient medium. The wavelength of the incident light can be changed, so that the light with a shorter wavelength is imaged by the first microlens array to form an object image with a smaller diameter, thereby improving the resolution of the imaging system. On the other hand, the refraction angle of the incident light passing through the first light-transmitting part 120 and the second light-transmitting part 130 in sequence and the refracted light entering the light-sensing element layer 200 after passing through the first microlenses 111 can be reduced, thereby reducing the refracted light. Crosstalk occurs between adjacent photosensitive elements 211, improving the performance of the photoelectric conversion device.

In some embodiments, the light-sensing element layer 200 further includes an interconnection layer 220, and the interconnection layer 220 transmits electrical signals of the photosensitive element 211, wherein the interconnection layer 220 may include a dielectric layer and a plurality of interconnection structures 221, wherein the plurality of interconnect structures 221 are arranged in the dielectric layer at intervals, and the plurality of interconnect structures 221 correspond to the plurality of photosensitive elements 211 one-to-one, so as to transmit the optical signal on each photosensitive element 211 to the peripheral circuit for reading out of the circuit.

The material of the dielectric layer may include insulating materials such as silicon oxide or silicon nitride, and the material of the interconnect structure 221 may include metal copper.

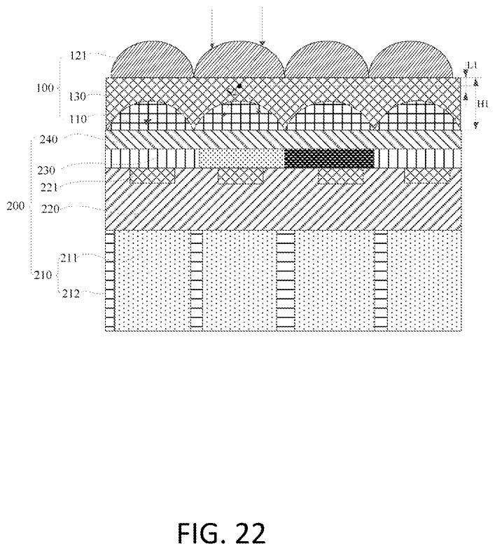

In this embodiment, the relative positional relationship among the interconnection layer 220, the photosensitive element layer 210 and the microlens array 100 can be selected in various ways. For example, as shown in FIG. 14 to FIG. 21, the photosensitive element layer 210 and the microlens array 100 is sequentially arranged on the interconnection layer 220, that is, the photosensitive element layer 210 is arranged between the microlens array 100 and the interconnection layer 220, so that the pixel array in the photoelectric conversion device is a backside illumination type (BSI for short) pixel array; for another example, as shown in FIG. 22, the interconnection layer 220 and the microlens array 100 are stacked on the photosensitive element layer 210, that is, the interconnection layer 220 is arranged between the photosensitive element layer 210 and the photosensitive element layer 210. Between the microlens arrays 100, the pixel array in the photoelectric conversion device is a front side illuminated (FSI for short) pixel array.

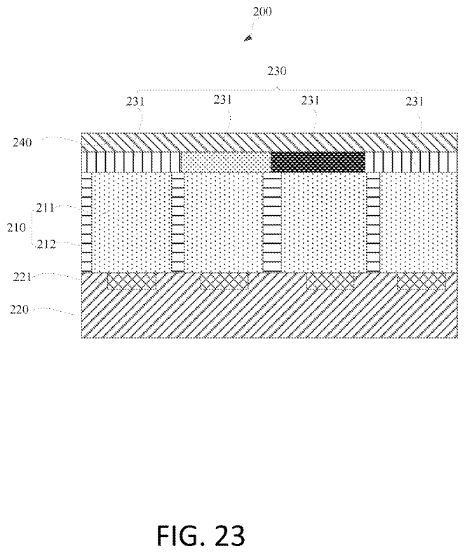

In some embodiments, as shown in FIG. 23, the light-sensing element layer 200 further includes a filter layer 230, the filter layer 230 includes a plurality of filter regions 231, and one filter region 231 corresponds to one or more first microlenses 111.

In this embodiment, through the arrangement of a plurality of filter regions, the required light of different wavelength bands can be obtained, so as to improve the imaging effect of the photoelectric conversion device.

Exemplarily, taking the orientation shown in FIG. 23 as an example, the first filter area 231 can only pass the light of the corresponding wavelength of red, the second filter area 231 can only pass the light of the corresponding wavelength of green, and the third filter area 231 can only pass the light of the corresponding wavelength of blue.

In some embodiments, an anti-reflection layer 240 is further disposed between the microlens array 100 and light-sensing element layer 200 to reduce the reflection of light, so that more light is transmitted to the photosensitive element 211, thereby ensuring the performance of the image sensor. The material of the anti-reflection layer 240 may be one or any combination of dielectric materials such as silicon oxide, hafnium oxide, silicon nitride, aluminum oxide, and thallium oxide.

It should be noted that, in this embodiment, the anti-reflection layer 240 may be a whole-layer structure, or may include a plurality of independently existing anti-reflection blocks, each of which corresponds to a photosensitive element 211 and a first microlens 111.

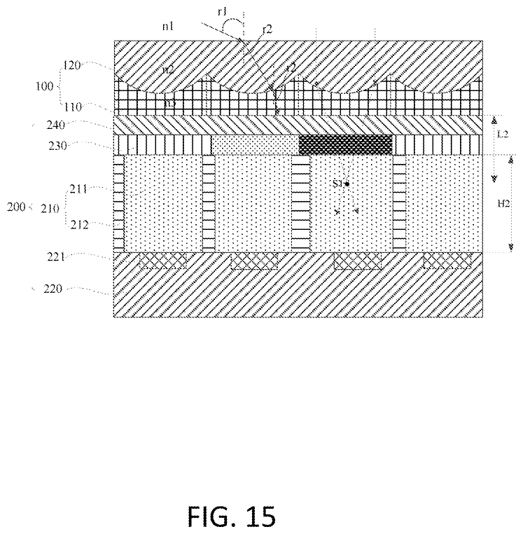

In some embodiments, with continued reference to FIGS. 14 and 15, each of the first microlenses 111 has a first focal point S1, the first focal point S1 is formed in the photosensitive element layer 210, the photosensitive element layer 210 has a second thickness H2, the first focal point S1 The maximum distance L2 from S1 to the bottom surface of the first .microlens 111 is not less than half of the second thickness H2. This setting can increase the focal length of the first .microlens 111 and prevent light from crosstalk into the adjacent photosensitive elements 211, which improves the performance of photoelectric conversion equipment.

### Embodiment 3

Another embodiment of the present disclosure also provides an imaging system, the imaging system may include a digital still camera, a digital video camera, an image reading device (e.g., a scanner), a mobile phone, and the like.

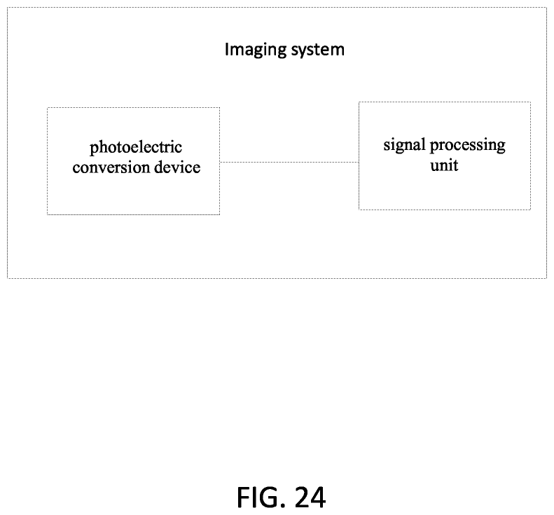

As shown in FIG. 24, the imaging system includes the photoelectric conversion device in the above embodiment and a signal processing unit, and the signal processing unit is used to process the output signal output from the photoelectric conversion device, so as to convert the output signal output by the photoelectric conversion device into a digital signal. For analog-to-digital conversion, the signal processing unit includes a microcomputer having a central processing unit (CPU), a read-only memory (ROM), a random access memory (RAM), and the like, and various circuits.

### Embodiment 4

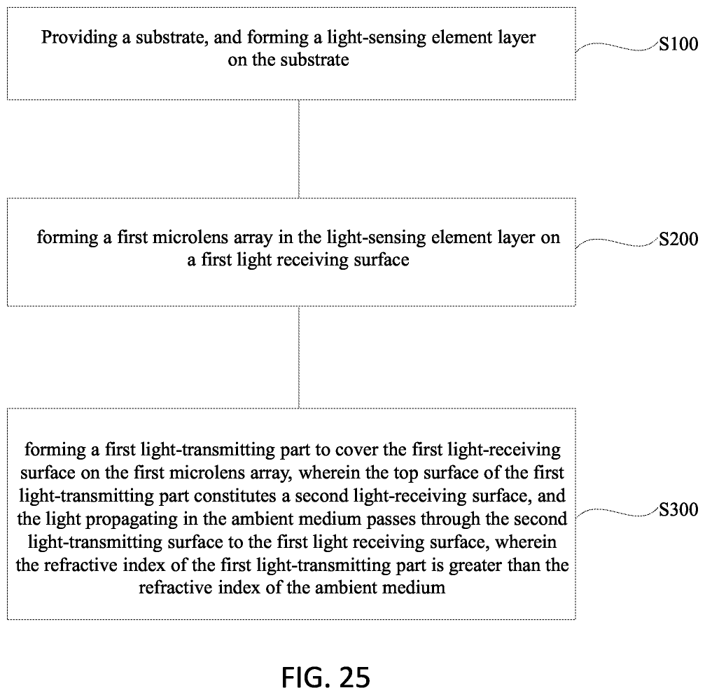

As shown in FIG. 25, an embodiment of the present disclosure further provides a method for manufacturing a photoelectric conversion device, including the following steps:

Step S100: providing a substrate, and forming a light-sensing element layer on the substrate.

The substrate may be made of a semiconductor material, and the semiconductor material may be one or more of silicon, germanium, silicon-germanium compound, and silicon-carbon compound.

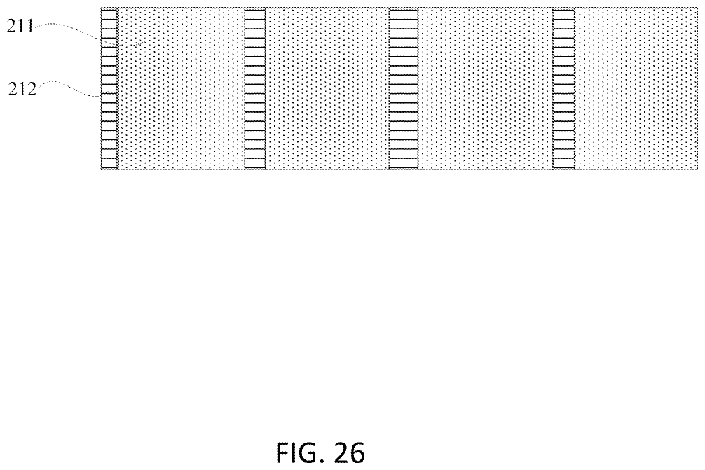

Exemplarily, as shown in FIG. 26, an isolation structure 212 may be formed in the substrate first to isolate the substrate into several independent photosensitive regions, and then different types of ions are doped into the substrate by ion implantation techniques. A P-type doped region and an N-type doped region are formed in the photosensitive region, and a PN junction is formed at the interface between the P-type doped region and the N-type doped region, that is, a photosensitive diode such as the photosensitive element 211 is formed in the photosensitive region.

It should be noted that, when the pixel array in the photoelectric conversion device is a front-illuminated pixel array, it is also necessary to form an interconnection layer 220 on the lower surface of the photosensitive element layer 210, and to form a filter layer on the upper surface of the photosensitive element layer 210. The layer 230 and the anti-reflection layer 240, wherein the formation process of the interconnect layer 220, the filter layer 230 and the anti-reflection layer 240 may be a conventional preparation process, which will not be described in this embodiment.

Step S200: forming a first microlens array in the light-sensing element layer on a first light receiving surface.

The first microlens array 110 includes a plurality of first microlenses 111, and the top surfaces of the plurality of first microlenses 111 constitute a first light receiving surface 112.

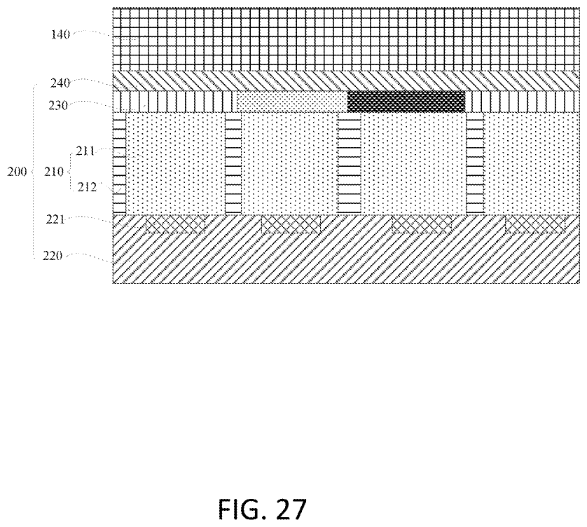

Exemplarily, as shown in FIG. 27, the first lens material layer 140 may be formed on the substrate on which the light-sensing element layer 200 is formed by a deposition process. It should be noted that, if the anti-reflection layer 240 has been formed in the above steps. This step may form the first lens material layer 140 on the anti-reflection layer 240.

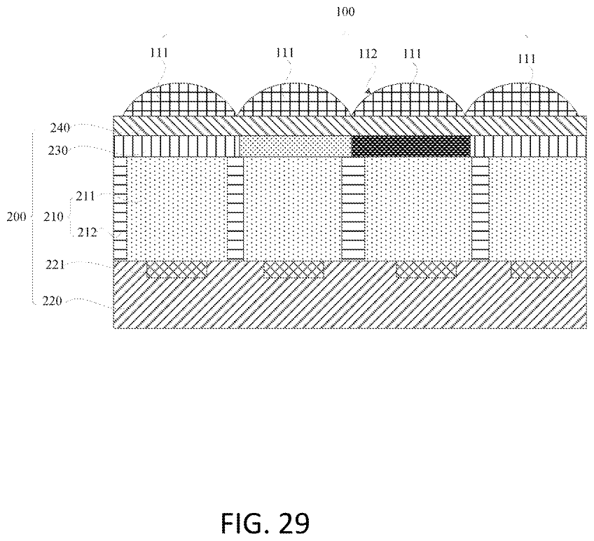

After that, the patterned first lens material layer 140 according to the optical design is formed, and a plurality of first microlenses 111 are formed which are connected to each other or arranged at intervals. The lens array 110 has a first light-receiving surface 112 whose structure is shown in FIG. 29.

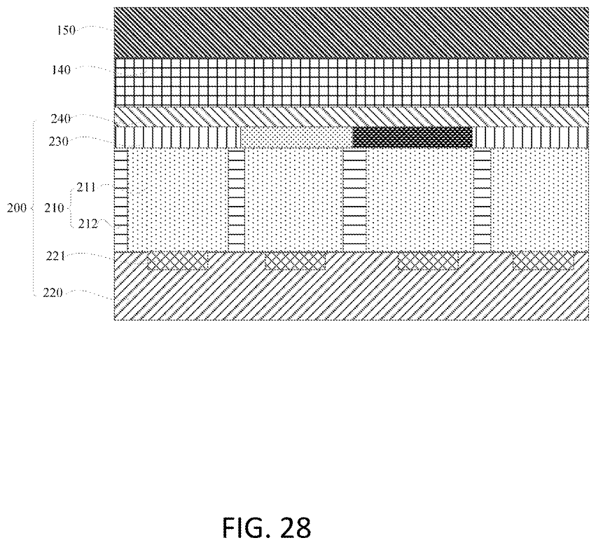

Exemplarily, as shown in FIG. 28, a photoresist layer 150 may be formed on the first lens material layer 140, and the photoresist layer 150 may be patterned to form a pattern in the photoresist layer 150, so that the patterned light resisting layer is a mask, part of the first lens material layer 140 is removed, and the remaining first lens material layer forms the plurality of first microlenses 111.

Step S300: forming a first light-transmitting part to cover the first light-receiving surface on the first microlens array, the top surface of the first light-transmitting part constitutes a second light-receiving surface, and the light propagating in the ambient medium passes through the second light-transmitting surface toward the first light receiving surface, wherein the refractive index of the first light-transmitting part is greater than the refractive index of the ambient medium.

In this embodiment, by forming the first light-transmitting part 120 with a larger refractive index on the first microlens array 110, the refractive index of the first light-transmitting part 120 is greater than the refractive index of the ambient medium. The wavelength of the incident light is changed, so that the light with a shorter wavelength is imaged by the first microlens array to form an object image with a smaller diameter, thereby improving the resolution of the imaging system. On the other hand, the refraction angle of the refracted light entering the light-sensing element layer 200 after the incident light passes through the first light-transmitting part 120, the second light-transmitting part 130 and the first microlens 111 in sequence can be reduced, and the refracted light in the phase can be reduced, so is the crosstalk occurrence between adjacent photosensitive elements 211, improving the performance of the photoelectric conversion device.

In some embodiments, after the step of forming the first microlens array in the light-sensing element layer, and before the step of forming the first light-transmitting part covering the first light-receiving surface on the first microlens array, the photoelectric conversion is fabricated with the method which includes the steps below.

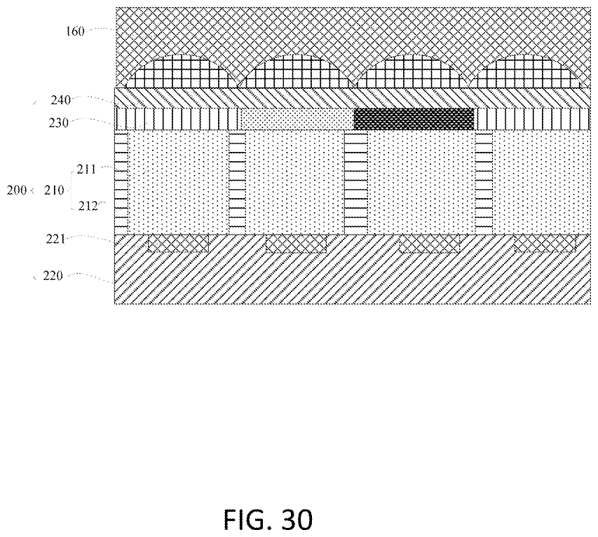

As shown in FIG. 30, a light-transmitting material layer 160 may be formed on the first microlens array 110 using a deposition process.

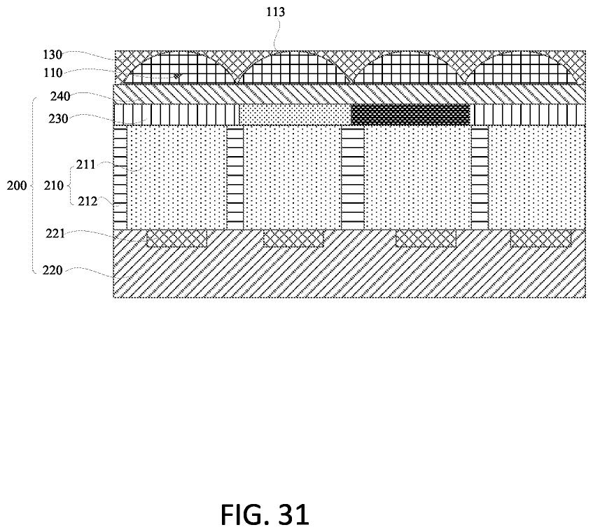

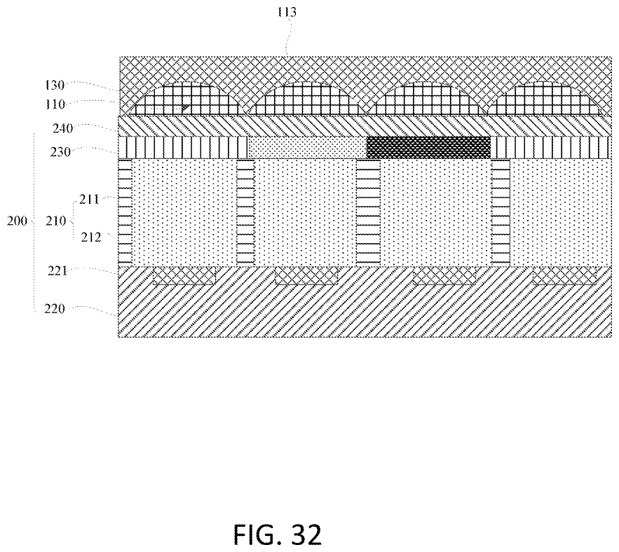

Afterwards, as shown in FIGS. 30, 31 and 32, the light-transmitting material layer 160 may be partially removed by etching to form a second light-transmitting part 130. The second light-transmitting part 130 has a flat top surface, wherein the refractive index of the second light-transmitting part 130 is smaller than that of the first light-transmitting part 120 and the first microlens array 110.

The height of the second light-transmitting part 130 is not limited in design, as long as the top surface of the second light-transmitting part 130 is flat.

In some embodiments, the step of forming the first light-transmitting part covering the first light-receiving surface on the first microlens array includes:

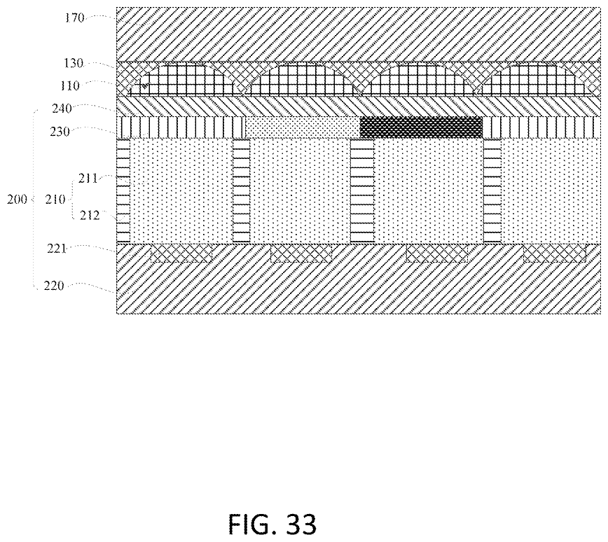

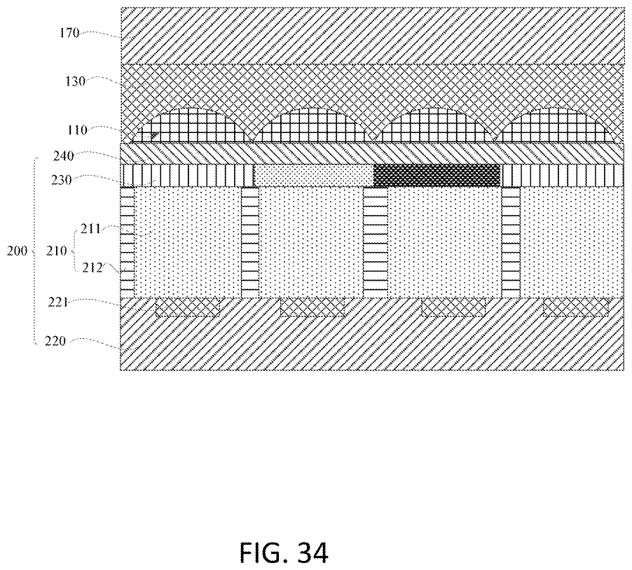

As shown in FIGS. 33 and 34, a second lens material layer 170 covering the second light-transmitting part 130 is formed by a deposition process. The refractive index of the second lens material layer 170 is greater than the refractive index of the first microlens array 110 and the refractive index of the first light-transmitting part 120, as well as greater than the refractive index of the ambient medium.

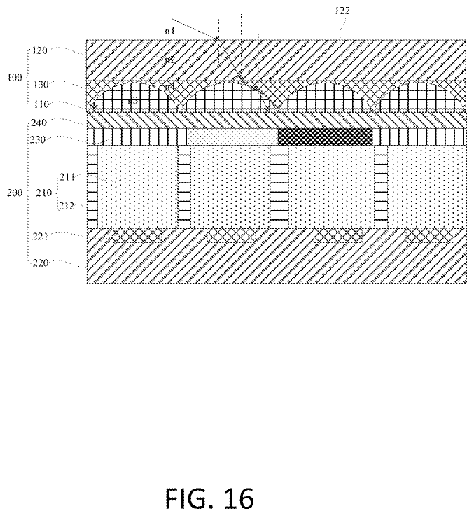

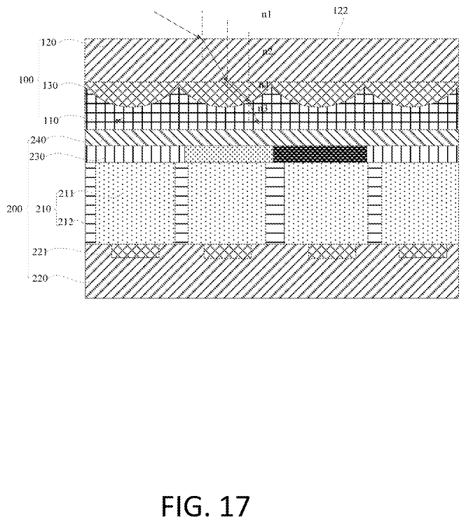

The second lens material layer 170 is patterned according to the optical design to form the first light-transmitting part 120. The top surface of the first light-transmitting part 120 constitutes the second light receiving surface 122, and the structure is shown in FIGS. 16 and 17.

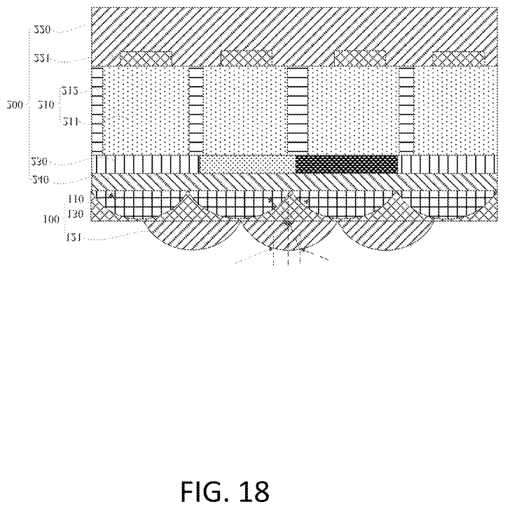

In some embodiments, the second lens material layer 170 is patterned to form a plurality of first light-transmitting elements 121 that are connected to each other or arranged at intervals. The structure may continue to refer to FIGS. 18 to 21.

Wherein, each of the first light-transmitting elements 121 includes a second microlens, a number of the second microlenses form the second microlens array, one second microlens corresponds to one or more first microlenses 111, and each of the first microlens 111 has a first curvature, each of the second microlenses has a second curvature, and the second curvature is different from the first curvature.

In this embodiment, the functions of the formed first light-transmitting part 120 and the second light-transmitting part 130 are the same as those of the first light-transmitting part 120 and the second light-transmitting part 130 in the first embodiment. Therefore this will not be repeated here.

The embodiments or implementations of this specification are described in a sequencial manner, and each embodiment focuses on the differences from other embodiments, and the same and similar parts between the various embodiments may be described or related to each other.

In the description of this specification, reference to the terms “one embodiment,” “some embodiments,” “exemplary embodiment,” “example,” “specific example,” or “some examples,” or the like, is meant to incorporate embodiments. A particular feature, structure, material, or characteristic described or exemplified is included in at least one embodiment or example of the present disclosure.

In this specification, schematic representations of the above terms do not necessarily refer to the same embodiment or example. Furthermore, the particular features, structures, materials or characteristics described may be combined in any suitable manner in any one or more embodiments or examples.

Finally, it should be noted that the above embodiments are only used to illustrate the technical solutions of the present disclosure, but not to limit them; although the present disclosure has been described in detail with reference to the foregoing embodiments, those of ordinary skill in the art should understand that: the technical solutions described in the foregoing embodiments can still be modified, or some or all of the technical features thereof can be equivalently replaced; and these modifications or replacements do not make the essence of the corresponding technical solutions deviate from the technical solutions of the embodiments' scope of the present disclosure.

1. A microlens array comprising:
a first microlens array;
a first light-transmitting part, wherein the first light-transmitting part is arranged on the first microlens array, wherein the first light-transmitting part transmits light propagating in an ambient medium to the first microlens array, wherein, a refractive index of the first light-transmitting part is greater than a refractive index of the ambient medium.

2. The microlens array of claim 1, wherein the refractive index of the first light-transmitting part is greater than a refractive index of the first microlens array.

3. The microlens array according to claim 1 or 2, further comprising a second light-transmitting part disposed between the first light-transmitting part and the first microlens array, wherein a refractive index of the second light-transmitting part is smaller than the refractive index of the first light-transmitting part and the refractive index of the first microlens array.

4. The microlens array of claim 1 or 2, wherein the first microlens array comprises a microconvex lens array or a microconcave lens array.

5. The microlens array according to claim 1 or 2, wherein the first microlens array comprises a plurality of first microlenses, wherein the first light-transmitting part comprises a plurality of first light-transmitting elements, wherein the first light-transmitting part corresponds to one or more of the first microlenses, and wherein the plurality of first microlenses comprises convex lenses or concave lenses.

6. The microlens array according to claim 5, wherein each of the first light-transmitting elements comprises a second microlens, wherein a plurality of the second microlenses forms a second microlens array, comprising one of the first light-transmitting elements and a second microlens array, and wherein the second microlens correspond to one or more of the plurality of the first microlenses.

7. The microlens array of claim 6, (need to be on 3) wherein the second microlens has a second focal point formed in the second light-transmitting part.

8. The microlens array of claim 7, wherein the second light-transmitting part has a first thickness, and wherein a maximum distance from the second focal point to a top surface of the second light-transmitting part is no greater than a half of the first thickness.

9. The microlens array of claim 7, wherein the plurality of the first microlenses has a first curvature and the second microlens has a second curvature, wherein the second curvature is different from the first curvature.

10. A photoelectric conversion device according to any one of claims 1-9, further comprising:
a light-sensing element layer, wherein the microlens array is disposed on the light-sensing element layer.

11. The photoelectric conversion device according to claim 10, wherein the light-sensing element layer comprises a filter layer, wherein the filter layer comprises a plurality of filter regions, and wherein one of the filter regions corresponds to one or more of the plurality of first microlenses.

12. The photoelectric conversion device according to claim 10, wherein the light-sensing element layer further comprises a photosensitive element layer, wherein the photosensitive element layer comprises a plurality of photosensitive elements, and wherein one of the photosensitive elements corresponds to one or more of the plurality of the first microlenses.

13. The photoelectric conversion apparatus of claim 12, wherein each of the plurality of the first microlenses has a first focus formed in the photosensitive element layer, wherein the photosensitive element layer has a second thickness, wherein a maximum distance from the first focal point to a bottom surface of said first microlens is not less than a half of the second thickness.

14. The photoelectric conversion device according to any one of claims 11-13, further comprising an anti-reflection layer, wherein the anti-reflection layer is disposed between the first microlens array and the first photosensitive element layer.

15. An imaging system according to any one of claims 10-14, further comprising:
a signal processing unit that processes a signal output from the photoelectric conversion device.

16. A method of manufacturing a photoelectric conversion device, comprising:
providing a substrate and forming a light-sensing element layer on the substrate;
forming a first microlens array in the light-sensing element layer on a first light receiving surface; and
forming a first light-transmitting part to cover a first light-receiving surface on the first microlens array, wherein a top surface of the first light-transmitting part constitutes a second light-receiving surface, and wherein a light propagating in an ambient medium passes through the second light-receiving surface to the first light receiving surface, and wherein a refractive index of the first light-transmitting part is greater than a refractive index of the ambient medium

17. The method of claim 16, wherein forming the first microlens array in the light-sensing element layer comprises:
depositing a first lens material layer on the substrate having the light-sensing element layer; and
patterning the first lens material layer according to an optical design to form a plurality of first microlenses connected to each other or arranged at intervals.

18. The method of claim 17, wherein after the forming the first microlens array in the light-sensing element layer, forming the first microlens array covering the first light receiving surface, before forming the light-transmitting part, the method further comprises:
forming a light-transmitting material layer on the first microlens array, wherein a refractive index of the light-transmitting material layer is smaller than a refractive index of the first microlens array;
removing a portion of a thickness of the light-transmitting material layer to form a second light-transmitting part, wherein the second light-transmitting part at least fills an area between adjacent two of the plurality of the first microlenses, wherein the second light-transmitting part has a flat top surface, and wherein a refractive index of the second light-transmitting part is smaller than a refractive index of the first light-transmitting part and the refractive index of the first microlens array.

19. The method of claim 18, wherein forming the first light-transmitting part covering the first light-receiving surface on the first microlens array comprises:
forming a second lens material layer covering the second light-transmitting part, wherein a refractive index of the second lens material layer is greater than the refractive index of the first microlens array and the refractive index of the second light-transmitting part; and
patterning the second lens material layer according to an optical design to form the first light-transmitting part.

20. The method of claim 19, wherein patterned the second lens material layer according to the optical design to form the first light-transmitting part comprises:
Patterning the second lens material layer to form a plurality of second light-transmitting elements that are connected to each other or arranged at intervals, wherein each of the second light-transmitting elements comprises a second microlens, wherein a plurality of the second microlenses form a second microlens array, and wherein one second microlens corresponds to one or more of the plurality of the first microlenses.
